(19) United States
(12) Patent Application Publication
(10) Pub. No.: US 2024/0282848 A1
(43) Pub. Date: Aug. 22, 2024

(54) DYNAMIC THRESHOLD VOLTAGE CONTROL OF POWER AMPLIFIERS

(71) Applicant: Analog Devices, Inc., Wilmington, MA (US)

(72) Inventors: James G. Fiorenza, Carlisle, MA (US); Christopher John Day, Santa Rosa, CA (US); Guanghai Ding, Bedford, MA (US); Daniel Piedra, Somerville, MA (US)

(21) Appl. No.: 18/560,066

(22) PCT Filed: Dec. 8, 2021
(86) PCT No.: PCT/US2021/062461

§ 371 Date: Nov. 9, 2023

(51) Int. Cl. H01L 29/778; H01L 29/20; H01L 29/40; H03K 17/687

(52) U.S. Cl. CPC H01L 29/7786; H01L 29/2003; H01L 29/407; H03K 17/687

(57) ABSTRACT

A semiconductor device including a transistor having a threshold voltage for switching the transistor from a first conductive state to a second conductive state. The transistor includes a first region formed by a first compound semiconductor material and a second region formed by a second compound semiconductor material, where the second region overlying the first region and forming a two-dimensional electron gas (2DEG) at a junction with the first region. The transistor further includes a buried field plate disposed proximate to the first region so that the 2DEG is interposed between the buried field plate and the second region. The semiconductor device further includes a control circuit configured to adjust the threshold voltage of the transistor by providing a bias voltage to the buried field plate responsive to an input signal received at the transistor.

### FIELD OF THE DISCLOSURE

This document pertains generally, but not by way of limitation, to semiconductor devices, and more particularly, to gallium nitride-based high electron mobility transistors.

### BACKGROUND

Gallium nitride-based semiconductors offer several advantages over other semiconductors as the material of choice for fabricating the next generation of transistors, or semiconductor switching devices, for use in both high-voltage and high-frequency applications. Gallium nitride (GaN) based semiconductors, for example, have wide bandgaps that enable devices fabricated from these materials to have a high breakdown electric field and to be robust to a wide range of temperatures. The two-dimensional electron gas (2DEG) channels formed by GaN based heterostructures generally have high electron mobility, making devices fabricated using these structures useful in power-switching and amplification circuits.

### BRIEF DESCRIPTION OF THE DRAWINGS

FIG. 1 depicts a diagram of an example of circuitry including a high electron mobility transistor having an adjustable threshold voltage.

FIG. 2 depicts a diagram of an example of a high electron mobility transistor having an adjustable threshold voltage.

FIG. 3 depicts a diagram of an example of a device layout of a high electron mobility transistor having an adjustable threshold voltage.

FIG. 4 illustrates an example of a process for operating a high electron mobility transistor having an adjustable threshold voltage.

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

### DETAILED DESCRIPTION

The present disclosure describes, among other things, a circuit for dynamically adjusting the threshold voltage of a gallium nitride-based high electron mobility transistor (HEMT) using an independently controlled buried field plate. The threshold voltage is controlled based on input voltage applied to the gate of the HEMT. This improves the gain and linearity of the HEMT under small and large signal conditions, thereby enabling the fabrication of devices having increased operating or dynamic range as compared to devices fabricated from using other transistors.

A figure of merit for an amplifier is the linearity of its gain response or a measure of how linearly the output of the amplifier tracks an input signal. A transistor, such as a HEMT, configured as an amplifier or used to amplify a signal, can provide a linear gain response when it is operated in the linear part of the current-voltage (I-V) transfer curve of the transistor. The transconductance curve of the transistor is typically flat within this region of operation, thereby ensuring a linear relationship between input voltage and output current. This linearly generally holds under small signal conditions, such as when the transistor or amplifier is configured to convert a small input voltage to a large output voltage. Under large signal conditions, however, the transistor's gain response becomes non-linear as the swing of the output current covers a wider portion of the transconductance (or I-V) curve, such as from the sub-threshold region of the curve where transconductance rises sharply to the maximum current region of the curve where transconductance drops sharply. The sharp transconductance rise and fall during the output current swing of a transistor operating under large signal conditions is one cause of linearity degradation or gain compression of amplifier circuits or devices.

Aspects of the present disclosure improves the gain and linearity of GaN HEMT-based amplifiers, such as GaN power amplifiers, by provided techniques (e.g., circuits, devices, systems, or methods) for dynamically adjusting the HEMT threshold voltage. In an example, the threshold voltage is adjusted responsive to an input signal applied to, or amplified by, the transistor. In an example, the threshold voltage is adjusted responsive to a swing, or change, in the amplitude of a voltage of the input voltage. In another example, the threshold voltage is adjusted responsive to the amplitude or frequency of the voltage or current of the input signal. According to these techniques, adjusting the threshold voltage of the HEMT dynamically shifts the transconductance verses input voltage curve of the transistor. Such dynamic control of the transconductance verses input voltage curve enables dynamic adjustment of the physical characteristics of the transistor such that the transistor is operated within the flattest region of the transconductance curve, thereby improving linearity of the transistor or an amplifier fabricated using the transistor. In an example, dynamically adjusting the threshold voltage of a HEMT enables the output voltage of the transistor, or an amplifier, fabricated using the transistor, to ride on the flattest part of the transistor's transconductance curve.

Examples of the present disclosure are based on the inventor's recognition that the threshold voltage of a GaN-based HEMT (hereinafter, “HEMT”) can be dynamically adjusted by controlling a bias signal (e.g., a bias voltage) applied to a buried field plate disposed under a two-dimensional electron gas (2DEG) of the transistor. Controlling the bias signal applied to the buried field plate enables the back-side potential of the HEMT to be dynamically adjusted. Controlling the back-side potential enables the electron concentration of the 2DEG to be dynamically controlled or adjusted, thereby enabling dynamic control of the HEMT threshold voltage.

In an example, a HEMT is formed on a substrate, such as a silicon carbide substrate, and includes a channel layer overlying the substrate and barrier layer overlying and in contact with the channel layer. The channel layer and the barrier layer include semiconductor material having different bandgaps such that a 2DEG is formed at the interface of these layers. The HEMT further includes a buried region having a low electrical resistance (e.g., an electrical resistance that is lower than the source-drain resistance of the HEMT). As an example, the buried region can have a low electrical resistance of about 50-500 ohm/sq. The buried region is disposed at least partially in the substrate under the channel laver. In an example, the buried region is configured, such as by its distance to the 2DEG, or by the activated dopant concentration of buried region, to operate as a buried field plate (e.g., a back-side field plate) to influence an electric field within the HEMT or to affect the concentration in the 2DEG. The HEMT further includes a field plate terminal that is electrically connected to the buried region (hereinafter, “buried field plate”) to enable a bias voltage to be controllably applied the region. In an example, the field plate terminal is electrically isolated from, or not connected to, a source, gate, or drain terminal of the HEMT.

In an example, circuitry for a HEMT transistor having an adjustable threshold voltage include a high electron mobility transistor having independent (e.g., electrically isolated) source, drain, gate and field plate terminals. The HEMT further includes a buried field plate that is connected to the field plate terminal. The circuitry further includes control circuitry that is configured to dynamically adjust the threshold voltage of the HEMT by controllably applying a bias voltage to the buried field plate. In an example, the control circuitry is configured to sample an input signal applied to the HEMT (e.g., an input signal applied to the gate, source, or drain of the HEMT) and apply, to the buried field plate, a bias voltage configured to adjust the threshold voltage of the transistor responsive to the sampled input signal. In an example, the threshold voltage is adjusted responsive to an amplitude or frequency of the input signal. In another example, the threshold voltage is adjusted responsive to a change in the amplitude or frequency of the input signal. In an example, the threshold voltage is adjusted to cause the HEMT to operate within a linear region of the transistors I-V curve during both small signal and large signal operation. In an example, the threshold voltage is adjusted to cause the output current of the HEMT to ride on an indicated region (e.g., a flat region) of the transistor's transconductance curve.

In an example, a method of operating a HEMT, such as to controllably adjust the threshold voltage of the transistor, includes detecting a signal applied to the transistor and adjusting the threshold voltage of the transistor responsive to the detected signal. Adjusting the threshold voltage include applying a bias signal (e.g., a bias voltage) to a buried field pate of the HEMT, wherein the bias signal is selected, determined, or configured, to adjust the threshold voltage of the transistor by controllably adjusting the electron concentration of the HEMT's 2DEG, or by adjusting an electric field within the transistor, such as the electric field under the gate of the transistor.

As used herein, the term “dynamic” refers to automatic or during operation of a device or circuitry, such as by operation of preconfigured circuitry or by execution of computer executable code during operation of a device or indicated circuitry. In an example, dynamically adjusting a threshold voltage of a transistor includes adjusting or changing the threshold voltage of the transistor during operation of the transistor or after the transistor is fabricated or configured in circuitry. In another example, dynamically adjusting a signal includes adjusting the amplitude, frequency, phase, or other characteristic of the signal during operation of a circuit that generates, receives, or uses the signal.

Examples of the present disclosure include lateral GaN HEMT transistors or switching devices formed using compound semiconductor materials. Such compound semiconductor materials may include a chemical compound of elements from different groups in the periodic table. Such chemical compounds may include a pairing of elements from group 13 (i.e., the group comprising boron (B), aluminum (Al), gallium (Ga), indium (In), and thallium (TI)) with elements from group 15 (i.e., the group comprising nitrogen (N), phosphorus (P), arsenic (As), antimony (Sb), and bismuth (Bi)). Group 13 of the periodic table may also be referred to as Group III and group 15 as Group V. Without limitation, a semiconductor device may be fabricated from gallium nitride (GaN) and aluminum indium gallium nitride (AlInGaN). Additionally, a semiconductor device may be fabricated using aluminum nitride (AlN)/GaN/AlN hetero-structures, indium aluminum nitride (InAlN)/GaN, GaN/aluminum nitride GaN (AlGaN), or other combinations of group 13 and group 15 elements. These hetero-structures may form a 2DEG at the interface of the compound semiconductors that form heterostructure, such as the interface of GaN and AlGaN. The 2DEG may form a conductive channel of electrons that may be controllably depleted, such as by an electric field formed by a gate terminal disposed above the channel, to control a current through the semiconductor device. In an example, the semiconductor device may be a field effect transistor, such as a high electron mobility transistor (HEMT), having source and drain terminals electrically coupled to a channel formed by a 2DEG, and a gate terminal disposed above the channel. A voltage on the gate terminal, determined relative to a voltage on the drain terminal, may induce an electric field into the channel to control the concentration of free electrons in the 2DEG, such as to control a flow of current through the transistor.

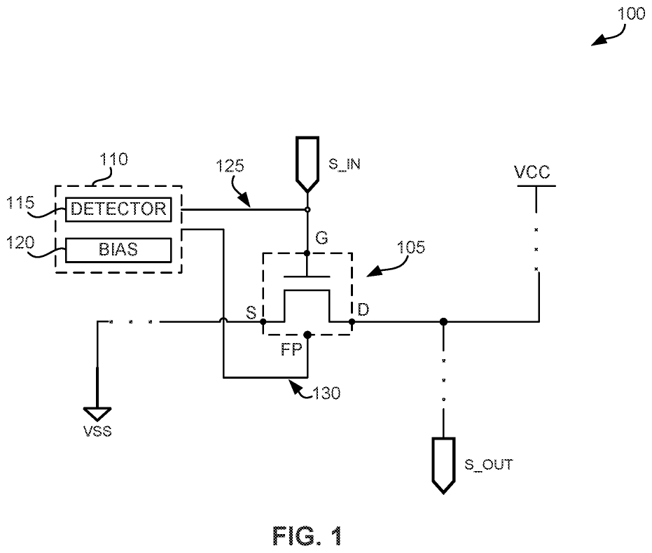

FIG. 1 depicts a diagram of an example of circuitry 100 including a high electron mobility transistor 105 having an adjustable threshold voltage. In an example, circuitry 100 is circuitry for an amplifier circuit, such as a power amplifier. In another example, circuitry 100 includes circuitry for operating or controlling a HEMT having an adjustable threshold voltage, as described herein. As shown in FIG. 1, circuitry 100 includes HEMT 105 and, optionally, control circuitry 110.

HEMT 105, in various examples, is a GaN-based transistor having a substrate, a channel layer made of a first compound semiconductor material, a barrier layer made of a second compound semiconductor material, and a buried field plate. The first and second compound semiconductor materials have respective different bandgaps, such that a 2DEG forms at their interface. In an example, the channel layer includes GaN material, and the barrier layer includes AlGaN material. In some examples, the buried field plate includes material having low electrical resistance. In an example, the buried field plate includes a heavily doped n-type material, such as silicon carbide (SiC) doped with nitrogen, phosphorus, or another n-type dopant. In another example, the buried field plate includes a heavily doped p-type material, such as SiC doped with beryllium, boron, aluminium, or gallium, or another p-type dopant. In yet another example, buried field plate includes a heavily doped n-type or p-type material.

HEMT 105 includes distinct source S, drain D, gate G, and field plate FP terminals. The field plate terminal FP is electrically connected to the buried field plate, such as to controllably apply a bias signal (e.g., a field plate bias voltage) to the buried field plate.

Control circuitry 110 include any circuit that is configured to provide or apply bias signal 130 (e.g., a bias voltage) to field plate terminal FP, such as to determine or adjust the threshold voltage of HEMT 105. In an example, control circuitry 110 is configured to provide bias signal 130 that is modulated by, or that varies in relationship with, an input signal S_IN applied to gate G of HEMT 105. In an example, control circuitry 110 is configured to change the amplitude of bias signal 130 responsive to changes in the amplitude or frequency of input signal S_IN. In various examples, control circuitry 110 includes detector circuitry 115 or bias circuitry 120.

Detector circuitry 115 includes any circuitry that is configured to sense or detect input signal S_IN. Such detection or sensing can include detecting the amplitude or frequency of S_IN. Such sensing or detecting can include detecting a change in the amplitude or frequency of S_IN. In an example detector circuitry 115 includes voltage or current sampling circuitry, comparator circuitry, amplifier circuitry, transconductance circuitry, or the like. In an example detector circuitry 115 is configured to obtain a sample 125 of input S_IN, condition the sample, and provide the conditioned sample to bias circuitry 120.

Bias circuitry 120 includes any circuitry that is configured to generate bias signal 130 or modulate bias signal 130, such as responsive to input signal S_IN. In an example, bias circuitry 120 is configured to receive data or another signal that is indicative of input signal S_IN from detector circuitry 115 and generate, modulate, or adjust bias signal 130 responsive to the received signal. In an example, bias circuitry 120 is configured to receive the data or other signal that is indicative of input signal S_IN at an input of comparator, operational amplifier, or differential amplifier circuitry, and evaluate the received signal against a reference signal to determine or generate bias signal 130. In an example, the reference signal is an analog reference of a digital reference, such as a table of predetermined digital values. In an example, the table of predetermined digital values associate a value (e.g., a voltage magnitude) of bias signal 130 with input signal S_IN or an indicated threshold voltage of HEMT 105.

In operation, circuitry 100 receives input signal S_IN at gate G of HEMT 105 and generates output signal S_OUT based on the threshold voltage or transconductance of the HEMT. Control circuitry 110 detects, such as through operation of detector circuitry 115, input signal S_IN and provides a bias signal 130 responsive to S_IN to change the threshold voltage of HEMT 105. In an example, the threshold voltage is increased responsive to an increase in the amplitude or frequency of input signal S_IN.

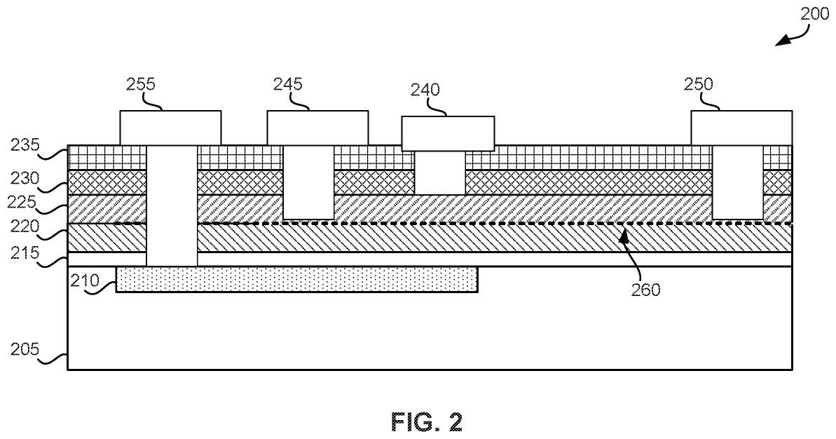

FIG. 2 depicts a diagram of an example of a high electron mobility transistor 200 having an adjustable threshold voltage. HEMT 200 is an example of one or more of the GaN-based high electron mobility transistors described herein, such as HEMT 105. In an example, HEMT 200 includes substrate layer 205, buried implant region 210, nucleation layer 215, a heterostructure formed by channel layer 220 and barrier layer 225, and capping layers 230 and 235. In some examples, HEMT 200 further includes gate contact 240, source contact 245, drain contact 250, and field plate contact 255. In an example, gate contact 240, source contact 245, drain contact 250, and field plate contact 255 are connected to, or correspond with, respective gate, source, drain, and field plate terminals of HEMT 200.

The substrate 205, in various examples, is a wafer, such as a wafer of a high-quality monocrystalline semiconductor material, such as sapphire (α-Al₂O₃), GaN, GaAs, Si, SiC in any of its polymorphs (including wurtzite), AlN, InP, or similar substrate material used in the manufacture of semiconductor devices. Such substrate may be received from a prior fabrication process, or it may be produced according to one or more substrate growth and processing techniques. In the examples described herein, substrate 205 is referred to as a SiC substrate for ease of discussion. Other substrates may be used to fabricate HEMT 200.

Buried implant region 210 may act as a buried field plate. In some examples, buried implant region 210 may be formed in a patterned region in the substrate 205, e.g., a silicon carbide substrate, where the patterned region is depicted conceptually as the rectangular boundary of buried implant region 210. Buried implant region 210 (e.g., a buried field plate), in various examples, includes a region of substrate 205 implanted with n-type dopants, such as a nitrogen or phosphorus n-type dopant, or one or more p-type dopants, such as beryllium, boron, aluminium, or gallium. In an example, substrate 205 can be processed to form buried implant region 210 by forming a mask on the surface of the substrate, where the mask is patterned to have a desired geometry (e.g., desired or indicated shapes or dimensions) of the of the implanted region. A dopant, such as a p-type dopant, can then be implanted, such as by using an ion implantation process or other suitable processes, into areas of substrate 205 that are exposed by the mask. The implanted dopants can then be electrically activated, such as to reduce the electrical or sheet resistance of buried implant region 210.

In another example, the substrate 205 is processed to form a buried implant region 210 by implanting a dopant, such as a p-type dopant, over a region of the substrate without using a mask. A mask can then be formed over the portions of the implanted region, where the mask is patterned to have a desired geometry (e.g., desired or indicated shapes or dimensions) of the of the implanted region. The mask can then be used to activate or deactivate dopants in portions of the implanted region.

In some examples, the buried field plate can be formed in a buried field plate layer, where the buried field plate layer includes an electrically active region of an n-type material defining the buried field plate, and an electrically inactive region of the n-type material proximate the electrically active region.

In other examples, the buried field plate can be formed in a buried field plate layer, where the buried field plate layer includes an electrically active region of a p-type material defining the buried field plate, and an electrically inactive region of the p-type material proximate the electrically active region. In an example, buried implant region 210 is formed using any suitable conductive material having a low sheet resistance.

Nucleation layer 215, in various examples, includes one or more layers of epitaxially grown nucleation or lattice transition layers. Nucleation layer 215 can help or facilitate epitaxial growth of one or more layers of semiconductor materials, such as GaN or channel layer 220. In an example. Nucleation layer 215 is formed or grown on the substrate 205 and buried implant region 210 using transmorphic epitaxy such that the nucleation layer has a high-quality crystalline structure presenting a rocking curve with a (002) peak FWHM below 100 arcseconds as indicated by x-ray diffraction. In an example, nucleation layer 215 has a height or thickness of 10 nm to 50 nm. In an example, nucleation layer 215 is an AlN nucleation layer that is formed or grown by transmorphic epitaxy and having a height or thickness of 10 nm to 50 nm.

Channel layer 220, in various examples, includes a GaN, AlGaN, or another compound semiconductor layer that is formed or grown on nucleation layer 215 using transmorphic epitaxy such that the channel layer has a high-quality crystalline structure presenting a rocking curve with a (102) peak FWHM below 300 arcseconds as indicated by x-ray diffraction. In certain examples, channel layer 220 is a GaN layer grown or formed using transmorphic epitaxy. In an example, channel layer 220 has a height or thickness of 100-350 nm. In certain examples, channel layer 220 has a height or thickness of 150 nm within an acceptable margin of error.

The thickness of the nucleation layer 215 or channel layer 220 can be selected or determined such that the distance between buried implant region 210 (e.g., a top surface of Buried implant region 210) and 2DEG 260 is small enough to enable buried implant region 210 to operate as a back-side field plate or otherwise affect the 2DEG as described herein. In an example, combined height or thickness of nucleation layer 215 and channel layer 220, within an acceptable margin of error, is between 100 nm and 400 nm.

Barrier layer 225, in various examples, includes a GaN, AlGaN, or another compound semiconductor layer that is formed or grown on channel layer 220 such that 2DEG 260 is formed at the interface between the barrier layer and the channel layer. In an example, barrier layer 225 is an AlGaN layer that is epitaxially grown on a GaN channel layer to form the 2DEG 260.

Gate 240 can be any electrically conductive material selected to bias or control HEMT 200. In another example, gate 240 includes a frontside field plate that is composed of the head and supported by layer 235.

Source contact 245 and drain contact 250 can be any suitable electrically conductive material capable of forming an ohmic contact or other electrically conductive junction with 2DEG region 260.

Field plate contact 255 can be any suitable electrically conductive material capable of forming an ohmic contact or other electrically conductive junction with buried implant region 210. In an example, field plate contact 255 is distinct, or electrically isolated, from gate 240, source contact 245, and drain contact 250, such as to enable independent control of a bias signal or bias voltage applied to buried implant region 210.

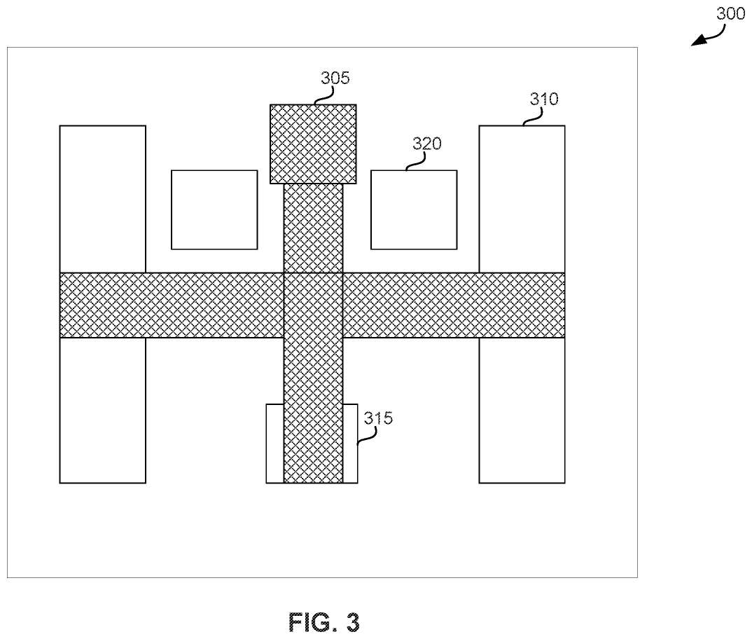

FIG. 3 depicts a diagram of an example of a device layout of a high electron mobility transistor 300 having an adjustable threshold voltage. HEMT 200 is an example of a layout of one or more of the GaN-based high electron mobility transistors described herein, such as HEMT 105 or HEMT 200. As shown in FIG. 3 HEMT 300 includes gate 305 (e.g., a gate region, contract, or terminal), source 310 (e.g., a source region, contact, or source terminal), drain 315 (e.g., a drain region, contact, or terminal), and field plate contact 320 (e.g., a field plate terminal).

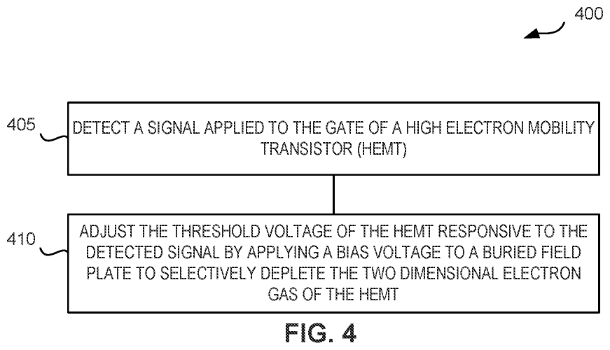

FIG. 4 illustrates an example of a process 400 for operating a high electron mobility transistor having an adjustable threshold voltage. Process 400 can be used to operate any of the HEMT devices, or any circuitry including an HEMT device, described herein, such as to dynamically adjust the threshold voltage of the transistor responsive to an input signal.

At 405, an input signal applied to an input of the HEMT is detected, such as by detector. In an example the input signal is detected by voltage, current, or frequency measuring circuitry, such as detector circuitry 115 (FIG. 1). Such detection can include sensing or measuring an amplitude or frequency of the input signal. Such detection can include sensing or measuring a change in the amplitude or frequency of the input signal. Such sensing or measuring can include obtaining a sample of the input signal, and comparing the sample to a reference signal, such as an indicated voltage, current or frequency.

At 410, the threshold voltage of the HEMT is adjusted responsive to the detected input signal. In an example adjusting the threshold voltage of the HEMT includes applying a bias signal (e.g., a field plate bias voltage) to the buried field plate, such as to adjust the backside potential of the transistor. In an example, adjusting the backside potential of the HEMT changes the threshold voltage of the transistor by modifying the electric field under the HEMT gate to increase or decrease the electron concentration of the HEMT's 2DEG. In an example, the threshold voltage is adjusted responsive to a change in the amplitude or frequency of the input signal.

Adjusting the threshold voltage of the HEMT can include determining a bias voltage to apply to the buried field plate of the HEMT to obtain an indicated change in the threshold voltage. Such determining can include comparing the input signal to a reference signal or a table of one or more predetermined reference signals and identifying a corresponding bias voltage, or bias voltage change, to obtain a target threshold voltage. Such determining or adjusting can include adjusting the bias signal from a first value corresponding to a first threshold voltage of the HEMT to a second value to a second threshold value of the HEMT responsive to a change in a magnitude of a voltage of the input signal. Such determining or adjusting can include adjusting the bias signal from a first value corresponding to a first threshold voltage of the HEMT to a second value to corresponding to a second threshold value of the HEMT responsive to a change in a frequency of the input signal.

In an example, adjusting the threshold voltage of the HEMT includes applying the bias signal to the buried field plate by applying the bias signal to a field plate terminal connected to the buried field plate, where the field plate terminal is electrically isolated from source, drain, and gate terminals of the high electron mobility transistor.

Example 1 is a semiconductor device comprising: a transistor having a threshold voltage for switching the transistor from a first conductive state to a second conductive state, the transistor including: a first region formed by a first compound semiconductor material: a second region formed by a second compound semiconductor material, the second region overlying the first region and forming a two-dimensional electron gas (2DEG) at a junction with the first region; and a buried field plate disposed proximate to the first region so that the 2DEG is interposed between the buried field plate and the second region; and a control circuit configured to adjust the threshold voltage of the transistor by providing a bias voltage to the buried field plate responsive to an input signal received at the transistor.

In Example 2, the subject matter of Example 1 includes, wherein the transistor includes: a gate terminal overlying an area of the second region formed by the second compound semiconductor material: source and drain terminals coupled to the 2DEG; and a control terminal coupled to the buried field plate to provide the bias voltage, the control terminal being separate from the gate, source, and drain terminals.

In Example 3, the subject matter of Examples 1-2 includes, wherein the transistor is configured to amplify the input signal, and the control circuit is configured to adjust the threshold voltage of the transistor responsive to at least one of: an amplitude of the input signal; a magnitude of a change to the input signal; or a frequency of the input signal.

In Example 4, the subject matter of Examples 1-3 includes, wherein the control circuit is configured to obtain a sample of the input signal, and adjust an amplitude of the bias voltage based on the obtained sample.

In Example 5, the subject matter of Examples 1˜4 includes, wherein the transistor comprises a gallium nitride high electron mobility transistor.

In Example 6, the subject matter of Example 5 includes, wherein the first compound semiconductor material comprises a gallium nitride material and the second compound semiconductor material comprises an aluminum gallium nitride material.

In Example 7, the subject matter of Example 6 includes, wherein the buried field plate includes an n-type semiconductor material.

In Example 8, the subject matter of Examples 1-7 includes, wherein the device includes a silicon carbide substrate, and buried field plate is formed in the silicon carbide substrate.

In Example 9, the subject matter of Examples 1-8 includes, wherein the buried field plate is formed in a buried field plate layer, the buried field plate layer including an electrically active region of an n-type material defining the buried field plate, and an electrically inactive region of the n-type material proximate the electrically active region.

Example 10 is a circuit for a high electron mobility transistor having an adjustable threshold voltage, the circuit comprising: a high electron mobility transistor having source, drain, gate, and a field plate terminals, the high electron mobility transistor including: a substrate; a gallium nitride (GaN) channel layer; an aluminum gallium nitride (AlGaN) barrier layer overlaying the channel layer, wherein a two-dimensional electron gas (2DEG) is interposed between the GaN channel layer and the AlGaN barrier layer; and a buried field plate underlying the 2DEG, the buried field plate coupled to the field plate terminal and configured to adjust a threshold voltage of the high electron mobility transistor responsive to a bias signal received at the field plate terminal.

In Example 11, the subject matter of Example 10 includes control circuitry coupled to the field plate terminal and configured to automatically adjust the bias signal responsive to a signal applied at the gate of the high electron mobility transistor.

In Example 12, the subject matter of Example 11 includes, wherein the control circuitry is configured to automatically adjust the bias signal responsive to the signal applied at the gate of the high electron mobility transistor by adjusting the bias signal to increase the threshold voltage responsive to an increase in an amplitude of the signal applied to the gate of the high electron mobility transistor.

In Example 13, the subject matter of Examples 11-12 includes, wherein the high electron mobility transistor includes a silicon carbide substrate, and buried field plate is formed in a patterned region in the silicon carbide substrate.

In Example 14, the subject matter of Examples 11-13 includes, wherein the buried field plate includes an p-type semiconductor material.

In Example 15, the subject matter of Examples 11-14 includes, wherein the control circuit is configured to adjust the bias signal to voltage of the high electron mobility transistor responsive to at least one of: an amplitude of the signal applied at the gate of the high electron mobility transistor; a magnitude of a change in the signal applied at the gate of the high electron mobility transistor; or a frequency of the signal applied at the gate of the high electron mobility transistor.

In Example 16, the subject matter of Examples 11-15 includes, wherein the buried field plate is formed in a buried field plate layer of the high electron mobility transistor, the buried field plate layer including an electrically active region of an n-type material defining the buried field plate, and an electrically inactive region of the n-type material proximate the electrically active region.

In Example 17, the subject matter of Examples 11-15 includes, wherein the buried field plate is formed in a buried field plate layer of the high electron mobility transistor, the buried field plate layer including an electrically active region of a p-type material defining the buried field plate, and an electrically inactive region of the p-type material proximate the electrically active region.

Example 18 is a method of operating a high electron mobility transistor, the method comprising: detecting a signal applied to a gate of the high electron mobility transistor; and adjusting a threshold voltage of the high electron mobility transistor responsive to the detected signal by: determining a field plate bias voltage to apply to a buried field plate underlying a two-dimensional electron gas (2DEG) of the high electron mobility transistor to adjust the threshold voltage by selectively depleting the 2DEG; and adjusting the threshold voltage by applying the field plate bias voltage to the buried field plate.

In Example 19, the subject matter of Example 18 includes, wherein determining the field plate bias voltage to apply to a buried field plate includes: adjusting the field plate bias voltage from a first value corresponding to a first threshold voltage of the high electron mobility transistor to a second value to corresponding to a second threshold value of the high electron mobility transistor responsive to a change in an amplitude of a voltage of the signal applied to a gate.

In Example 20, the subject matter of Examples 18-19 includes, wherein determining the field plate bias voltage to apply to a buried field plate includes: adjusting the field plate bias voltage from a first value corresponding to a first threshold voltage of the high electron mobility transistor to a second value to corresponding to a second threshold value of the high electron mobility transistor responsive to a change in a frequency of the signal applied to a gate.

In Example 21, the subject matter of Examples 18-20 includes, wherein applying the field plate bias voltage to the buried field plate includes applying the field plate bias voltage to a field plate terminal connected to the buried field plate, the field plate terminal being electrically isolated from source, drain, and gate terminals of the high electron mobility transistor.

Example 22 is at least one machine-readable medium including instructions that, when executed by processing circuitry, cause the processing circuitry to perform operations to implement of any of Examples 1-21.

Example 23 is an apparatus comprising means to implement of any of Examples 1-21.

Example 24 is a system to implement of any of Examples 1-21.

Example 25 is a method to implement of any of Examples 1-21.

The present disclosure discusses device structures (e.g., semiconductor device structures) and techniques for forming hybrid wide band gap power devices, such as power transistors. These devices include hybrid silicon carbide devices, such as devices that include vertical silicon carbide device structures that are bonded and electrically coupled to device structures (e.g., lateral device structures) that are fabricated from other substrates, such as a silicon (Si), gallium nitride (GaN), or gallium arsenide (GaAs) substrate.

As used herein, the term epitaxy refers to the formation (e.g., deposition or growth) of a crystalline layer or film on the surface of crystalline substrate, whereby the formed layer takes on the crystal structure and lattice properties of the substrate. Epitaxy may be used in semiconductor device fabrication to form thin-films of single crystals. Epitaxy may be performed in the vapor phase, liquid phase, or solid phase. In some embodiments, molecular beam epitaxy (“MBE”) may be used for growing semiconductor crystals from elements in groups 13 and 15, although it should be appreciated that other forms of epitaxy may be used with the techniques described herein.

The present disclosure uses the terms switch, switching device, or switching element synonymously. A switch, switching device, or switching element can include one or more electronically controlled switches such as an electromechanical switch, transistor, or other controllable semiconductor device. As used herein, a conductivity type of a material refers to the type of the majority charge carries in the material. The conductivity types discussed herein are n-type, such as to corresponding to a majority electron charge carrier, or p-type, such as to correspond to a majority hole charge carrier. The indicator of the conductivity type of a material (e.g., “n” or “p”) can include a positive sign (e.g., “+”) or a negative sign (e.g., “−”) to indicate a concentration of dopants or majority charge carriers in the material relative to a concentration of dopants or majority charge carriers in another material. Materials having positive conductivity type indicators have higher dopant or charge carrier concentrations than materials with negative conductivity type indicators. In an example, an n+ layer has a higher dopant concentration than an n layer, which has a higher dopant concentration than an n− layer.

The substrates, device layers, or device regions are described herein with references to specific conductivity types. It should be appreciated, however, that the conductivity type of such substrates, devices layers, or device regions can be switched to an opposite conductivity type or polarity, such as to fabricate a device with the opposite conductivity type. In an example, the conductivity type of the substrates, devices lavers, or device regions of n-type MOSFETs (e.g., NMOS devices) can be inverted or switched to corresponding opposite conductivity types to fabricate p-type MOSFETs (e.g., PMOS devices).

The above detailed description includes references to the accompanying drawings, which form a part of the detailed description. The drawings show, by way of illustration, specific embodiments in which the invention may be practiced. These embodiments are also referred to herein as “examples.” Such examples may include elements in addition to those shown or described.

However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B.” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first.” “second,” and “third,” etc. are used merely as labels, and are not intended to impose numerical requirements on their objects.

Method examples described herein may be machine or computer-implemented at least in part. Some examples may include a computer-readable medium or machine-readable medium encoded with instructions operable to configure an electronic device to perform methods as described in the above examples. An implementation of such methods may include code, such as microcode, assembly language code, a higher-level language code, or the like. Such code may include computer readable instructions for performing various methods. The code may form portions of computer program products. Further, in an example, the code may be tangibly stored on one or more volatile, non-transitory, or non-volatile tangible computer-readable media, such as during execution or at other times. Examples of these tangible computer-readable media may include, but are not limited to, hard disks, removable magnetic disks, removable optical disks (e.g., compact discs and digital video discs), magnetic cassettes, memory cards or sticks, random access memories (RAMs), read only memories (ROMs), and the like.

The above description is intended to be illustrative, and not restrictive. For example, the above-described examples (or one or more aspects thereof) may be used in combination with each other. Other embodiments may be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments may be combined with each other in various combinations or permutations. The scope of the invention should be determined with reference to the appended claims, along with the full scope of equivalents to which such claims are entitled.

1. A semiconductor device comprising:
a transistor having a threshold voltage for switching the transistor from a first conductive state to a second conductive state, the transistor including:
a first region formed by a first compound semiconductor material;
a second region formed by a second compound semiconductor material, the second region overlying the first region and forming a two-dimensional electron gas (2DEG) at a junction with the first region; and
a buried field plate disposed proximate to the first region so that the 2DEG is interposed between the buried field plate and the second region; and
a control circuit configured to adjust the threshold voltage of the transistor by providing a bias voltage to the buried field plate responsive to an input signal received at the transistor.

2. The semiconductor device of claim 1, wherein the transistor includes:
a gate terminal overlying an area of the second region formed by the second compound semiconductor material;
source and drain terminals coupled to the 2DEG; and
a control terminal coupled to the buried field plate to provide the bias voltage, the control terminal being separate from the gate, source, and drain terminals.

3. The semiconductor device of claim 1, wherein the transistor is configured to amplify the input signal, and the control circuit is configured to adjust the threshold voltage of the transistor responsive to at least one of:
an amplitude of the input signal;
a magnitude of a change to the input signal; or
a frequency of the input signal.

4. The semiconductor device of claim 1, wherein the control circuit is configured to obtain a sample of the input signal, and adjust an amplitude of the bias voltage based on the obtained sample.

5. The semiconductor device of claim 1, wherein the transistor comprises a gallium nitride high electron mobility transistor.

6. The semiconductor device of claim 5, wherein the first compound semiconductor material comprises a gallium nitride material and the second compound semiconductor material comprises an aluminum gallium nitride material.

7. (canceled)

8. The semiconductor device of claim 1, wherein the semiconductor device includes a silicon carbide substrate, and buried field plate is formed in the silicon carbide substrate.

9. The semiconductor device of claim 1, wherein the buried field plate is formed in a buried field plate layer, the buried field plate layer including an electrically active region of an n-type material defining the buried field plate, and an electrically inactive region of the n-type material proximate the electrically active region.

10. The semiconductor device of claim 1, wherein the buried field plate is formed in a buried field plate layer, the buried field plate layer including an electrically active region of a p-type material defining the buried field plate, and an electrically inactive region of the p-type material proximate the electrically active region.

11. A circuit for a high electron mobility transistor having an adjustable threshold voltage, the circuit comprising:
a high electron mobility transistor having source, drain, gate, and a field plate terminal, the high electron mobility transistor including:
a substrate;
a gallium nitride (GaN) channel layer;
an aluminum gallium nitride (AlGaN) barrier layer overlaying the GaN channel layer, wherein a two-dimensional electron gas (2DEG) is interposed between the GaN channel layer and the AlGaN barrier layer; and
a buried field plate underlying the 2DEG, the buried field plate coupled to the field plate terminal and configured to adjust a threshold voltage of the high electron mobility transistor responsive to a bias signal received at the field plate terminal.

12. The circuit of claim 11, further comprising control circuitry coupled to the field plate terminal and configured to automatically adjust the bias signal responsive to a signal applied at the gate of the high electron mobility transistor.

13. The circuit of claim 12, wherein the control circuitry is configured to automatically adjust the bias signal responsive to the signal applied at the gate of the high electron mobility transistor by adjusting the bias signal to increase the threshold voltage responsive to an increase in an amplitude of the signal applied to the gate of the high electron mobility transistor.

14. The circuit of claim 12, wherein the high electron mobility transistor includes a silicon carbide substrate, and the buried field plate is formed in a patterned region in the silicon carbide substrate.

15. (canceled)

16. (canceled)

17. The circuit of claim 12, wherein the control circuitry is configured to adjust the bias signal to voltage of the high electron mobility transistor responsive to at least one of:
an amplitude of the signal applied at the gate of the high electron mobility transistor;
a magnitude of a change in the signal applied at the gate of the high electron mobility transistor; or
a frequency of the signal applied at the gate of the high electron mobility transistor.

18. The circuit of claim 12, wherein the buried field plate is formed in a buried field plate layer of the high electron mobility transistor, the buried field plate layer including an electrically active region of an n-type material defining the buried field plate, and an electrically inactive region of the n-type material proximate the electrically active region.

19. The circuit of claim 12, wherein the buried field plate is formed in a buried field plate layer of the high electron mobility transistor, the buried field plate layer including an electrically active region of a p-type material defining the buried field plate, and an electrically inactive region of the p-type material proximate the electrically active region.

20. A method of operating a high electron mobility transistor, the method comprising:
detecting a signal applied to a gate of the high electron mobility transistor; and
adjusting a threshold voltage of the high electron mobility transistor responsive to the detected signal by:
determining a field plate bias voltage to apply to a buried field plate underlying a two-dimensional electron gas (2DEG) of the high electron mobility transistor adjust the threshold voltage by selectively depleting the 2DEG; and
adjusting the threshold voltage by applying the field plate bias voltage to the buried field plate.

21. The method of claim 20, wherein determining the field plate bias voltage to apply to a buried field plate includes:
adjusting the field plate bias voltage from a first value corresponding to a first threshold voltage of the high electron mobility transistor to a second value to corresponding to a second threshold value of the high electron mobility transistor responsive to a change in an amplitude of a voltage of the signal applied to a gate.

22. The method of claim 20, wherein determining the field plate bias voltage to apply to a buried field plate includes:
adjusting the field plate bias voltage from a first value corresponding to a first threshold voltage of the high electron mobility transistor to a second value to corresponding to a second threshold value of the high electron mobility transistor responsive to a change in a frequency of the signal applied to a gate.

23. The method of claim 20, wherein applying the field plate bias voltage to the buried field plate includes applying the field plate bias voltage to a field plate terminal connected to the buried field plate, the field plate terminal being electrically isolated from source, drain, and gate terminals of the high electron mobility transistor.
